(19) United States
(12) Patent Application Publication
(10) Pub. No.: US 2026/0128110 A1
(43) Pub. Date: May 7, 2026

(54) MAGNETIC MEMORY DEVICE

(71) Applicant: SAMSUNG ELECTRONICS CO., LTD., Suwon-si (KR)

(72) Inventor: Dae Shik KIM, Suwpn-si (KR)

(73) Assignee: SAMSUNG ELECTRONICS CO., LTD., Suwon-si (KR)

(21) Appl. No.: 19/279,579

(22) Filed: Jul. 24, 2025

(30) Foreign Application Priority Data
Nov. 6, 2024 (KR) 10-2024-0156533

(51) Int. Cl. G11C 17/18; G11C 17/16

(52) U.S. Cl. CPC G11C 17/18; G11C 17/16

(57) ABSTRACT

A magnetic memory device, including: a cell array including: a memory cell comprising a first magnetic tunnel junction element, and a one-time-programmable (OTP) cell comprising a second magnetic tunnel junction element; and a control circuit configured to perform a read operation on the OTP cell by applying a write current to the OTP cell, and determining whether a resistance of the OTP cell changes after the write current is applied to the OTP cell.

### CROSS-REFERENCE TO RELATED APPLICATIONS

This application is based on and claims priority under 35 U.S.C. § 119 to Korean Patent Application No. 10-2024-0156533, filed on Nov. 6, 2024, in the Korean Intellectual Property Office, the disclosure of which is incorporated by reference herein in its entirety.

### BACKGROUND OF THE DISCLOSURE

### 1. Field

The disclosure relates to a magnetic memory device.

### 2. Description of Related Art

As electronic devices become faster and power consumption is reduced, it is increasingly desirable for memory devices to have a high-speed read/write operation and a low operating voltage, which may be provided, for example, by magnetic memory devices. Because magnetic memory devices may be non-volatile and capable of operating at a high speed, they are attracting attention as next-generation memories.

One example of a magnetic memory device is a spin transfer torque (STT) magnetic random access memory (MRAM), which may be referred to as STT-MRAM, which may store information using an STT phenomenon. An STT-MRAM may store information by applying a current directly to a magnetic tunnel junction element to induce a magnetization reversal. A highly integrated STT-MRAM may provide high-speed operation and low current operation.

A one-time-programmable (OTP) memory may refer to a non-volatile memory in which data is permanently retained using one program operation. An OTP may be used in an application field in which data stability and security are important, with the aim of recording specific information only once and continuing to read it. Because the OTP memory is programmable only once, the information cannot be changed, which ensures the integrity and reliability of the data. The OTP memory may be used in applications in which reliability and security are desirable. For example, the OTP memory may be utilized to store information such as a digital security token, a smart card, a key, a password, a booting code, and a manufacturing/production setting, and may be incorporated as part of a semiconductor chip or provided as an independent chip. If OTP memory is incorporated as part of a chip, it can be implemented at low cost without affecting the performance of the core logic when fully compatible with the logic complementary metal-oxide-semiconductor (CMOS) process.

### SUMMARY

Provided is a magnetic memory device that may perform a read operation of a one-time-programmable (OTP) cell without a reference resistor.

However, aspects of the present disclosure are not restricted to the one set forth herein. Additional aspects will be set forth in part in the description which follows and, in part, will be apparent from the description, or may be learned by practice of the presented embodiments.

In accordance with an aspect of the disclosure, a magnetic memory device includes: a cell array including: a memory cell comprising a first magnetic tunnel junction element, and a one-time-programmable (OTP) cell comprising a second magnetic tunnel junction element; and a control circuit configured to perform a read operation on the OTP cell by applying a write current to the OTP cell, and determining whether a resistance of the OTP cell changes after the write current is applied to the OTP cell.

In accordance with an aspect of the disclosure, a magnetic memory device includes: a cell array including: a memory cell comprising a first magnetic tunnel junction element and a first cell transistor, and an OTP cell comprising a second magnetic tunnel junction element and a second cell transistor; and a control circuit configured to: apply a write current to the memory cell to perform a write operation on the memory cell, and apply the write current to the OTP cell to perform a read operation on the OTP cell.

In accordance with an aspect of the disclosure, a magnetic memory device includes: a cell array comprising a reference cell including a first magnetic tunnel junction element, a memory cell, and an OTP cell including a second magnetic tunnel junction element; and a control circuit configured to: perform a read operation on the memory cell using the reference cell, apply a write current to the OTP cell, and perform a read operation on the OTP cell based on a change in a magnitude of a current flowing through the reference cell or the write current.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is an exemplary block diagram of a magnetic memory device according to some embodiments;

FIG. 2 is exemplary circuit diagram for explaining the magnetic memory device according to some embodiments;

FIG. 3 is exemplary circuit diagram for explaining the memory cell according to some embodiments;

FIG. 4 is an exemplary circuit diagram for explaining a one-time-programmable (OTP) cell according to some embodiments;

FIG. 5 is a diagram for explaining the resistance of the memory cells and the OTP cells according to some embodiments;

FIG. 6 is a flowchart for explaining a read operation of the OTP cell according to some embodiments;

FIG. 7 is a diagram for explaining the read operation of the OTP cell according to some embodiments;

FIG. 8 is a diagram for explaining the read operation of the memory cell according to some embodiments;

FIG. 9 is a flowchart for explaining the read operation of the OTP cell according to some embodiments;

FIG. 10 is a diagram for explaining the read operation of the OTP cell according to some embodiments;

FIG. 11 is a diagram for explaining the read operation of the memory cell according to some embodiments;

FIG. 12 is a diagram for explaining the read operation of the OTP cell;

FIGS. 13 and 14 are diagrams for explaining an operation of the magnetic memory device according to some embodiments;

FIG. 15 is a flowchart for explaining the read operation of the OTP cell according to some embodiments;

FIG. 16 is an exemplary circuit diagram for explaining the magnetic memory device according to some embodiments;

FIG. 17 is an exemplary circuit diagram for explaining the magnetic memory device according to some embodiments; and

FIG. 18 is an exemplary circuit diagram for explaining the magnetic memory device according to some embodiments.

### DETAILED DESCRIPTION OF THE EMBODIMENTS

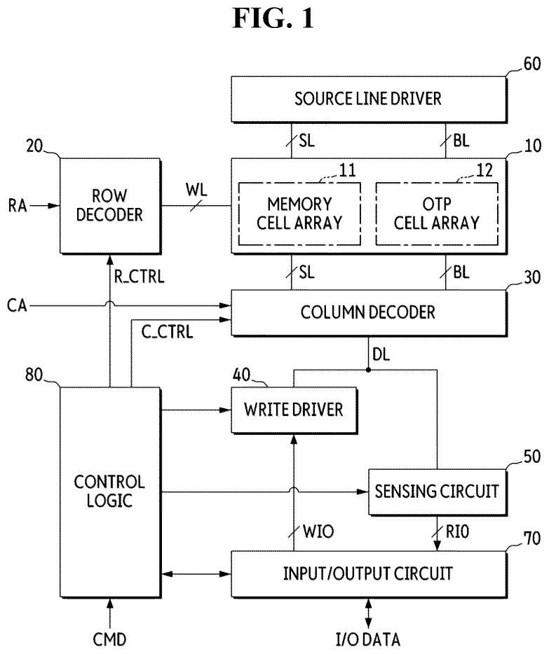

FIG. 1 is an exemplary block diagram of a magnetic memory device according to some embodiments.

Referring to FIG. 1, the magnetic memory device according to some embodiments may include a cell array 10, a row decoder 20, a column decoder 30, a write driver 40, a sensing circuit 50, a source line driver 60, an input/output circuit 70, and a control logic 80.

The cell array 10 may include a plurality of memory blocks. The memory blocks include a memory cell array 11 and a one-time-programmable (OTP) cell array 12. The memory cell array 11 may include a plurality of memory cells connected to word lines WL and bit lines BL. The OTP cell array 12 may include a plurality of OTP cells connected to the word lines WL and the bit lines BL.

The memory cells and the OTP cells may be configured to store data. The memory cells and the OTP cells may include, for example, a variable resistance element, for example, a magnetic tunnel junction (MTJ) element, in which the value of the stored data may be discriminated based on a resistance value of the MTJ element.

For example, the memory cells and the OTP cells may include a random access memory (RAM) such as a resistive RAM (ReRAM), a phase change RAM (PRAM), a ferroelectric RAM (FRAM), and the like, and may include a magnetic RAM (MRAM), such as a spin-transfer torque MRAM (STT-MRAM), a spin torque transfer magnetization switching RAM (Spin-RAM), and a spin momentum transfer RAM (SMT-RAM).

The row decoder 20 may select (or drive) a word line WL connected to a memory cell on which a read operation or a program operation is performed based on a row address RA and a row control signal R_CTRL. The row decoder 20 may provide a drive voltage, which is input from the control logic 80, to the selected word line.

The column decoder 30 may select a bit line BL and/or a source line SL connected to a memory cell on which a read operation or a program operation is performed based on a column address CA and a column control signal C_CTRL. The column decoder 30 may connect the selected bit line BL and source line SL to a data line DL.

The write driver 40 may drive a program voltage (or write current) for storing write data in a memory cell selected by the row decoder 20 and the column decoder 30 at a time of a program operation. For example, at the time of the program operation, the write driver 40 may control the voltage of a data line DL write data, which may correspond to input/output data I/O DATA received from the input/output circuit 70 through the write input/output line WIO, thereby storing the write data (e.g., the input/output data I/O DATA) in the selected memory cell.

The sensing circuit 50 may sense a signal that is output through the data line DL at the time of the read operation to discriminate the value of data stored in the memory cell. The sensing circuit 50 may be connected to the column decoder 30 through the data line DL, and may be connected to the input/output circuit 70 through the read input/output line RIO. The sensing circuit 50 may provide the sensed read data to the input/output circuit 70 through the read input/output line RIO, and the input/output circuit 70 may output the sensed read data as input/output data I/O DATA.

The source line driver 60 may drive the source line SL at a specific voltage level under the control of the control logic 80. For example, the source line driver 60 may be supplied with a voltage for driving the source line SL from the control logic 80.

The input/output circuit 70 may receive input/output data I/O DATA which is received from the outside, and may provide this input/output data I/O DATA as write data to the write driver 40. In addition, the input/output circuit 70 may read data from the sensing circuit 50, and may output this read data as input/output data I/O DATA to the outside.

The control logic 80 may control the overall operation of the magnetic memory device. For example, the control logic 80 may control the row decoder 20, the column decoder 30, the write driver 40, the sensing circuit 50, the source line driver 60, the input/output circuit 70, and the like. In addition, the control logic 180 may operate in response to command CMD or control signals that are input from the outside. The command CMD may include a read command, a write command, etc.

Hereinafter, the row decoder 20, the column decoder 30, the write driver 40, the sensing circuit 50, the source line driver 60, the input/output circuit 70, and the control logic 80 may be referred to as a control circuit.

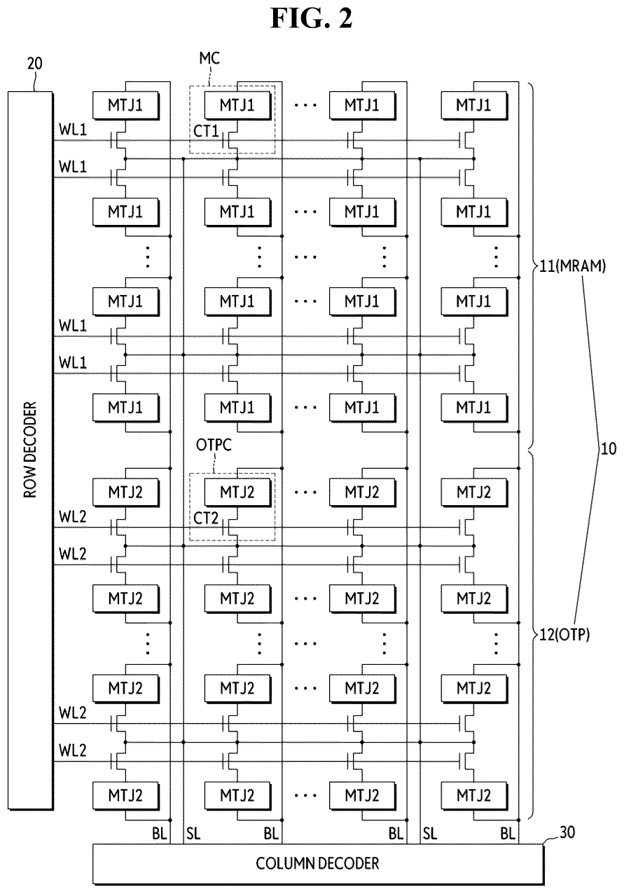

FIG. 2 is an exemplary circuit diagram for explaining a magnetic memory device according to some embodiments.

Referring to FIG. 2, the cell array 10 according to some embodiments may include a memory cell array 11 and an OTP cell array 12. The memory cell array 11 may include a plurality of memory cells MC arranged along a row direction and a column direction. The OTP cell array 12 may include a plurality of OTP cells OTPC arranged along the row direction and the column direction.

In some embodiments, the OTP cells OTPC may be connected to a specific word line. The memory cells MC and the OTP cells OTPC may be connected to word lines that are different from each other. For example, the memory cells MC may be connected to a first word line WL1, and the OTP cells OTPC may be connected to a second word line WL2 different from the first word line WL1. The memory cells MC and the OTP cells OTPC may be connected to one bit line BL.

The placement of the memory cell array 11 and the OTP cell array 12 may be varied in the cell array 10. For example, the OTP cell array 12 may be disposed at an edge portion of the cell array 10. The OTP cells OTPC may be connected to a second word line WL2 disposed at the edge portion of the cell array 10.

The memory cells MC may be connected to first word lines WL1, bit lines BL, and source lines SL. Each memory cell MC may include a first magnetic tunnel junction element MTJ1 and a first cell transistor CT1.

A gate of the first cell transistor CT1 may be connected to the first word line WL1. The first cell transistor CT1 may be turned on or off by a signal or voltage provided to the first word line WL1. The gates of the first cell transistors CT1 disposed in the row direction may be commonly connected to one first word line WL1.

One end (e.g., a first end) of the first cell transistor CT1 may be connected to one end (e.g., a first end) of the first magnetic tunnel junction element MTJ1. Another end (e.g., a second end) of the first cell transistor CT1 may be connected to a source line SL. Second ends of the pair of adjacent first cell transistors CT1 may be commonly connected to one source line.

One end (e.g., a second end) of the first magnetic tunnel junction element MTJ1 may be connected to a bit line BL, and another end (e.g., a first end) of the first magnetic tunnel junction element MTJ1 may be connected to one end (e.g., the first end) of the first cell transistor CT1. One end (e.g., the second end) of the first magnetic tunnel junction elements MTJ1 arranged in the column direction may be commonly connected to one bit line BL.

The memory cell MC may be programmable multiple times. The memory cell MC may be switched between two resistance states by an electric pulse applied to the first magnetic tunnel junction element MTJ1. The memory cell MC may be used as an MRAM.

The OTP cells OTPC may be connected to second word lines WL2, bit lines BL, and source lines SL. The OTP cell OTPC may include a second magnetic tunnel junction element MTJ2 and a second cell transistor CT2.

The second cell transistor CT2 and the first cell transistor CT1 may be gated to word lines that are different from each other. For example, a gate of the second cell transistor CT2 may be connected to the second word line WL2, and a gate of the first cell transistor CT1 may be connected to the first word line WL1. The second cell transistor CT2 may be turned on or off by a signal or voltage provided to the second word line WL2. The gates of the second cell transistors CT2 disposed in the row direction may be commonly connected to one second word line WL2.

One end (e.g., a first end) of the second cell transistor CT2 may be connected to one end (e.g., a first end) of the second magnetic tunnel junction element MTJ2. The other end (e.g., a second end) of the second cell transistor CT2 may be connected to the source line SL. Second ends of the adjacent pair of second cell transistors CT2 may be commonly connected to one source line SL.

One end (e.g., a second end) of the second magnetic tunnel junction element MTJ2 may be connected to the bit line BL, and another end (e.g., the first end) of the second magnetic tunnel junction element MTJ2 may be connected to one end (e.g., the first end) of the second cell transistor CT2. One end (e.g., the second end) of the second magnetic tunnel junction elements MTJ2 arranged in the column direction may be commonly connected to one bit line BL.

The OTP cell OTPC may be programmable only once. The programmed second magnetic tunnel junction element MTJ2 may have an irreversible resistance state. The OTP cell OTPC may be used as an OTP memory.

Each of the first cell transistor CT1 and the second cell transistor CT2 may include, for example, at least one of a diode, a PNP bipolar transistor, an NPN bipolar transistor, an N-type metal-oxide-semiconductor (NMOS)field effect transistor, and a P-type metal-oxide-semiconductor (PMOS)field effect transistor.

Because the OTP cells OTPC may be connected to a specific word line (e.g., the second word line WL2), the memory cells MC and also the OTP cells OTPC may be used to perform an error correction code (ECC).

In some embodiments, each of the memory cells MC and the OTP cells OTPC may have a structure in which one cell transistor (e.g., a first cell transistor CT1 or a second cell transistor CT2) is connected to one magnetic tunnel junction element (e.g., a first magnetic tunnel junction element MTJ1 or a second magnetic tunnel junction element MTJ2). In some other embodiments, each of the memory cells MC and the OTP cells OTPC may have a structure in which two cell transistors are connected to one magnetic tunnel junction element (e.g., a first magnetic tunnel junction element MTJ1 or a second magnetic tunnel junction element MTJ2). The number of first cell transistors included in the memory cell MC and the number of second cell transistors included in the OTP cell OTPC are not limited thereto, but may be various. In addition, the number of first cell transistors CT1 included in the memory cell MC may be different from the number of second cell transistors CT2 included in the OTP cell OTPC. The cell array 10 may be electrically connected to a peripheral circuit. The peripheral circuit may include, for example, the row decoder 20, the column decoder 30, the write driver 40, the sensing circuit 50, the source line driver 60, the input/output circuit 70, the control logic 80 and the like of FIG. 1. The memory cells MC and the OTP cells OTPC may be electrically connected to the peripheral circuit. For example, the memory cells MC and the OTP cells OTPC may share the peripheral circuits.

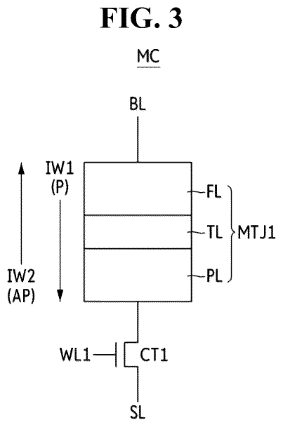

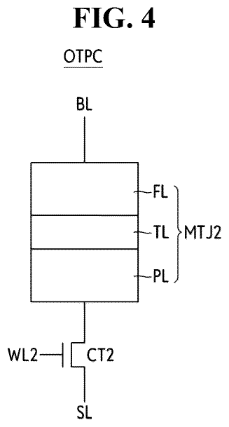

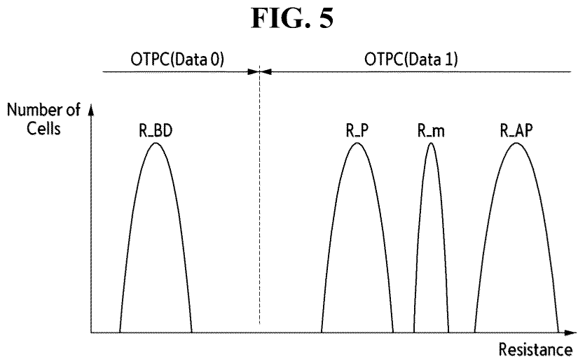

FIG. 3 is an exemplary circuit diagram for explaining a memory cell according to some embodiments. FIG. 4 is an exemplary circuit diagram for explaining an OTP cell according to some embodiments. FIG. 5 is a diagram for explaining the resistance of the memory cells and the OTP cells according to some embodiments.

Referring to FIGS. 3 and 5, a memory cell MC may include a first magnetic tunnel junction element MTJ1, which may include a pinned layer PL, a tunnel layer TL, and a free layer FL. The tunnel layer TL may be interposed between the pinned layer PL and the free layer FL.

The pinned layer PL may have a magnetization direction that is pinned regardless of an external magnetic field, and the free layer FL may have a magnetization direction that is changeable to be parallel or anti-parallel to the magnetization direction of the pinned layer PL.

The first magnetic tunnel junction element MTJ1 may store data in the memory cell MC, using a difference in electrical resistance due to the magnetization direction of the pinned layer PL and the magnetization direction of the free layer FL.

To perform a write operation on the memory cell MC, a turn-on voltage may be applied to the first word line WL1, and the write voltage may be applied to both ends of the first magnetic tunnel junction element MTJ1. Based on the direction of the write voltage applied to both ends of the first magnetic tunnel junction element MTJ1, a first write current IW1 or a second write current IW2 may flow through the first magnetic tunnel junction element MTJ1.

For example, when a relatively high-level voltage (e.g., a write voltage) is applied to the bit line BL and a relatively low voltage (e.g., a ground voltage) is applied to the source line SL, a first write current IW1 flowing from the bit line BL to the source line SL may be supplied or provided to the first magnetic tunnel junction element MTJ1. In this case, electrons having the same spin direction as the pinned layer PL may tunnel through the tunnel layer TL and apply a torque to the free layer FL. As a result, a state of the first magnetic tunnel junction element MTJ1 may become a parallel state P in which the magnetization direction of the free layer FL is parallel to the magnetization direction of the pinned layer PL, the first magnetic tunnel junction element MTJ1 may have a first resistance value R_P and may store data representing a value of zero (“0”). For example, the memory cell MC may be written to the parallel state P, using the first write current IW1.

When a relatively high-level voltage (e.g., a write voltage) is applied to the source line SL and a relatively low voltage (e.g., a ground voltage) is applied to the bit line BL, a second write current IW2 flowing from the source line SL to the bit line BL may be provided to the first magnetic tunnel junction element MTJ1. In this case, electrons having a spin opposite to that of the pinned layer PL fail to tunnel through the tunnel layer TL, and may be reflected to the free layer FL to apply a torque to the free layer FL. As a result, the state of the first magnetic tunnel junction element MTJ1 may be changed to an anti-parallel state AP in which the magnetization direction of the free layer FL is anti-parallel to the magnetization direction of the pinned layer PL, and the first magnetic tunnel junction element MTJ1 may have a second resistance value R_AP and may store data representing a value of one (“1”). The second resistance value R_AP may be larger than the first resistance value R_P. For example, the memory cell MC may be written to the anti-parallel state AP, using the second write current IW2.

As a result, the memory cell MC may have a first resistance value R_P or a second resistance value R_AP based on the write currents IW1 and IW2 flowing through the first magnetic tunnel junction element MTJ1, and may be implemented as a plurality of programmable memory cells.

A reference resistor value R_m for the read operation of the memory cell MC may be determined. The reference resistor value R_m may have a value between the first resistance value R_P and the second resistance value R_AP.

Although examples are described herein in which the free layer FL is connected to the bit line BL, and the pinned layer PL is connected to the first cell transistor CT1, embodiments are not limited thereto. For example, in some embodiments, the pinned layer PL may be connected to the bit line BL, and the free layer FL may be connected to the first cell transistor CT1.

In some embodiments, each of the pinned layer PL and the free layer FL may have a magnetization easy axis perpendicular to an interface between the pinned layer PL and the free layer FL.

Each of the pinned layer PL and the free layer FL may include at least one of a perpendicular magnetic material (as an example, CoFeTb, CoFeGd, and CoFeDy), a perpendicular magnetic material having an L10 structure, CoPt of a hexagonal close packed lattice structure, and a perpendicular magnetic structure. The perpendicular magnetic material having the L10 structure may include, for example, FePt of an L10 structure, FePd of an L10 structure, CoPd of an L10 structure, CoPt of an L10 structure or the like. The perpendicular magnetic structure may include magnetic layers and nonmagnetic layers that are alternately and repeatedly stacked. For example, the perpendicular magnetic structure may include (Co/Pt)ₙ, (CoFe/Pt)ₙ, (CoFe/Pd)ₙ, (Co/Pd)ₙ, (Co/Ni)ₙ, (CoNi/Pt)ₙ, (CoCr/Pt)ₙ, or (CoCr/Pd)ₙ (here, n is the number of stacks), etc.

In some embodiments, each of the pinned layer PL and the free layer FL may have a magnetization easy axis parallel to the interface between the pinned layer PL and the free layer FL.

Each of the pinned layer PL and the free layer FL may include a ferromagnetic material. In some embodiments, the pinned layer PL may further include an antiferromagnetic material for fixing the magnetization direction of the ferromagnetic material. For example, the ferromagnetic material may include at least one of CoFeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and Y3Fe5012. For example, the antiferromagnetic material may include at least one of PtMn, IrMn, MnO, MnS, MnTe, MnF2, FeCl2, FeO, CoCl2, CoO, NiCl2, NiO, and Cr, or at least one selected from precious metal. The precious metal may include ruthenium (Ru), rhodium (Rh), palladium (Pd), osmium (Os), iridium (Ir), platinum (Pt), gold (Au) or silver (Ag). The free layer FL may be made up of a plurality of layers.

The tunnel layer TL may include, for example, at least one selected from oxides of magnesium (Mg), titanium (Ti), aluminum (Al), magnesium-zinc (MgZn) and magnesium-boron (MgB), and nitrides of titanium (Ti) and vanadium (V).

Referring to FIGS. 4 and 5, the OTP cell OTPC may have substantially the same structure as the memory cell MC. The second magnetic tunnel junction element MTJ2 may include a pinned layer PL, a tunnel layer TL and a free layer FL. The tunnel layer TL may be interposed between the pinned layer PL and the free layer FL. Each of the pinned layer PL, the tunnel layer TL, and the free layer FL of the second magnetic tunnel junction element MTJ2 may be formed of the same material as the pinned layer PL, the tunnel layer TL, and the free layer FL of the first magnetic tunnel junction element MTJ1.

A part of the OTP cell OTPC may be in a state in which the second magnetic tunnel junction element MTJ2 is dielectrically broken down, and the rest may be in a state in which the second magnetic tunnel junction element MTJ2 is not dielectrically broken down.

A part of the OTP cell OTPC may apply a break-down voltage to both ends of the second magnetic tunnel junction element MTJ2 through one program operation, and the second magnetic tunnel junction element MTJ2 may have an irreversible resistance state based on dielectric break-down of the tunnel layer TL. The break-down voltage may cause a break-down current to flow through the second magnetic tunnel junction element MTJ2. The magnitude of the break-down current may be greater than the magnitude of the first write current IW1 and the magnitude of the second write current IW2. The second magnetic tunnel junction element MTJ2 which is dielectrically broken down may be in a short state. The second magnetic tunnel junction element MTJ2 which is dielectrically broken down may have a third resistance value R_BD and may store data representing a value of zero (“0”). The second magnetic tunnel junction element MTJ2 without being dielectrically broken down may have a resistance value greater than the third resistance value R_BD and may store data representing a value of one (“1”). A state of the second magnetic tunnel junction element MTJ2 without being dielectrically broken down may be a parallel state P or an anti-parallel state AP.

As a result, the OTP cell OTPC may be programmable only once, and the tunnel layer TL may have a state of being dielectrically broken down or a state of being not dielectrically broken down, and may be used as an OTP.

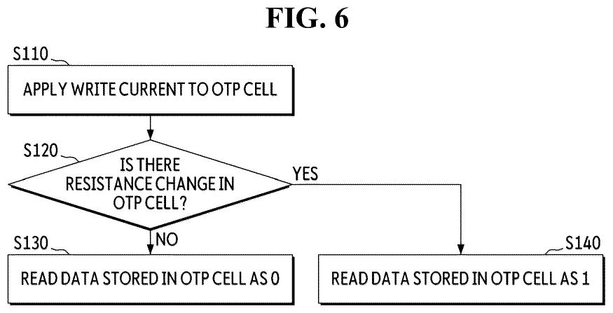

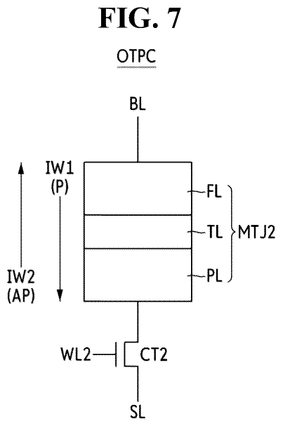

FIG. 6 is a flowchart for explaining a read operation of the OTP cell according to some embodiments. FIG. 7 is a diagram for explaining a read operation of the OTP cell according to some embodiments.

Referring to FIGS. 6 and 7, write currents may be applied to the OTP cell OTPC at operation S110. The write currents may include, for example, at least one of a first write current IW1 for writing the memory cell MC to the parallel state P and a second write current IW2 for writing the memory cell MC to the anti-parallel state AP. Next, it is possible to determine whether there is a change in resistance of the OTP cell OTPC at operation S120. If there is no change in resistance of the OTP cell OTPC at operation S120, the data stored in the OTP cell OTPC may be read as having a value of zero (“0”) at operation S130. If there is a change in the resistance of the OTP cell OTPC at operation S120, the data stored in the OTP cell OTPC may be read as having a value of one (“1”) at operation S140.

For example, when data representing a value of zero (“0”) is stored in the OTP cell OTPC, because the second magnetic tunnel junction MTJ2 of the OTP cell OTPC is in a state of being dielectrically broken down, even if the write currents IW1 and IW2 are applied to the OTP cell OTPC, the resistance of the OTP cell OTPC may not change. However, when data representing a value of one (“1”) is stored in the OTP cell OTPC, because the second magnetic tunnel junction MTJ2 of the OTP cell OTPC is in a state of not being dielectrically broken down, the second magnetic tunnel junction MTJ2 may be changed to a parallel state P or an anti-parallel state AP, by the first write current IW1 or the second write current IW2. For example, the resistance of the second magnetic tunnel junction element MTJ2 may be changed to a first resistance value R_P or a second resistance value R_AP.

When the second magnetic tunnel junction element MTJ2 of the OTP cell OTPC is not dielectrically broken down and is in an anti-parallel state AP, when the first write current IW1 is applied to the second magnetic tunnel junction element MTJ2 of the OTP cell OTPC, the second magnetic tunnel junction element MTJ2 of the OTP cell OTPC may be changed to the parallel state P. For example, the resistance value of the second magnetic tunnel junction element MTJ2 of the OTP cell OTPC may be changed from the second resistance value R_AP to the first resistance value R_P. When the second magnetic tunnel junction element MTJ2 of the OTP cell OTPC is not dielectrically broken down and is in the anti-parallel state AP, the second magnetic tunnel junction element MTJ2 of the OTP cell OTPC may maintain the anti-parallel state AP when the second write current IW2 is applied to the second magnetic tunnel junction element MTJ2 of the OTP cell OTPC. For example, the resistance value of the second magnetic tunnel junction element MTJ2 of the OTP cell OTPC may be maintained at the second resistance value R_AP.

When the second magnetic tunnel junction element MTJ2 of the OTP cell OTPC is not dielectrically broken down and is in the parallel state P, the second magnetic tunnel junction element MTJ2 of the OTP cell OTPC may maintain the parallel state P when the first write current IW1 is applied to the second magnetic tunnel junction element MTJ2 of the OTP cell OTPC. For example, the resistance value of the second magnetic tunnel junction element MTJ2 of the OTP cell OTPC may be maintained at the first resistance value R_P. When the second magnetic tunnel junction element MTJ2 of the OTP cell OTPC is not dielectrically broken down and is in the parallel state P, the second magnetic tunnel junction element MTJ2 of the OTP cell OTPC may be changed to the anti-parallel state AP, when the second write current IW2 is applied to the second magnetic tunnel junction element MTJ2 of the OTP cell OTPC. For example, the resistance value of the second magnetic tunnel junction element MTJ2 of the OTP cell OTPC may be changed from the first resistance value R_P to the second resistance value R_AP.

Therefore, if there is no resistance change of the OTP cell OTPC after the first write current IW1 is applied to the OTP cell OTPC, and there is no resistance change of the OTP cell OTPC after the second write current IW2 is applied to the OTP cell OTPC, the data stored in the OTP cell OTPC may be determined to have a value of zero (“0”), and if there is a resistance change of the OTPC cell OTPC after the first write current IW1 or the second write current IW2 is applied to the OTP cell OTPC, the data stored in the OTP cell OTPC may be determined to have a value of one (“1”). The read operation of the OTP cell OTPC may be performed by the control circuit of FIG. 1.

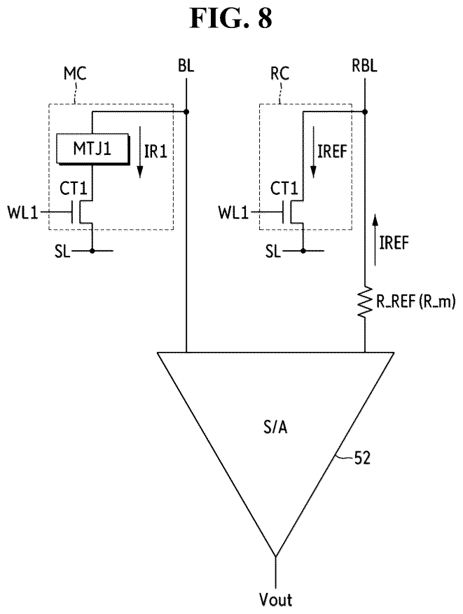

FIG. 8 is a diagram for explaining a read operation of the memory cell according to some embodiments.

Referring to FIG. 8, at least one of the bit lines BL may be used as a reference bit line RBL. The memory cells MC connected to the reference bit line RBL and the OTP cells OTPC connected to the reference bit line RBL may be used as the reference cell RC. The cell array (e.g., the cell array 10 of FIG. 1) may include memory cells MC, OTP cells OTPC, and reference cells RC. The reference cells RC may be connected to a specific bit line, (e.g., the reference bit line RBL). In some embodiments, the reference cells RC may be connected to a specific word line. An example in which the reference cells RC are connected to the reference bit line RBL is described below.

In some embodiments, the memory cells MC may perform the read operation, using a reference resistor R_REF having a fixed resistance value. The read operation of the memory cells MC may be performed by the control circuit of FIG. 1.

In some embodiments, the reference cells RC may include only the first cell transistor CT1. For example, the reference cells RC may not include a magnetic tunnel junction element. The reference cells RC may be connected to the reference resistor R_REF. For example, the reference resistor R_REF may be provided between the reference bit line RBL to which the reference cells RC are connected and a sense amplifier 52. The reference resistor R_REF may be connected in series to the reference bit line RBL to which the reference cells RC are connected. The reference resistor R_REF may have a constant resistance value (e.g., the reference resistor value R_m of FIG. 5). For example, the reference resistor R_REF may be implemented as gate polysilicon used to generate the gate electrode of a transistor (e.g., the first cell transistor CT1) in the process of manufacturing a magnetic memory device. In this case, the resistance value of the reference resistor R_REF may be adjusted by adjusting the length, thickness, width, and the like of the gate polysilicon.

At the time of the read operation of the memory cell MC, a reference cell RC connected to the same first word line WL1 as the memory cell MC to be read may be used. For the read operation of the memory cell MC, a turn-on voltage may be applied to the first word line WL1 of the memory cell MC and the reference cell RC, and the read voltage may be applied to both ends of the memory cell MC and both ends of the reference cell RC. For example, the read voltage may be applied to the bit line BL of the memory cell MC and the reference bit line RBL of the reference cell RC, and the ground voltage may be applied to the source line of the memory cell MC and the source line of the reference cell RC. Accordingly, the first read current IR1 may flow through the memory cell MC, and the reference current IREF may flow through the reference cell RC and the reference resistor R_REF.

The sense amplifier 52 may sense a difference between the voltage of the node to which the first read current IR1 is applied and the voltage of the node to which the reference current IREF is applied, and amplify the difference. The difference of the amplified voltage may be output as an output voltage Vout, and may be used to discriminate data that is read from the memory cell MC. For example, the sense amplifier 52 may determine whether the first read current IR1 is greater than the reference current IREF.

For example, if the first read current IR1 is greater than the reference current IREF, the data stored in the memory cell MC may be read as having a value of zero (“0”), and if the first read current IR1 is smaller the reference current IREF, the data stored in the memory cell MC may be read as having a value of one (“1”). The sense amplifier 52 may be included, for example, in the sensing circuit 50 of FIG. 1.

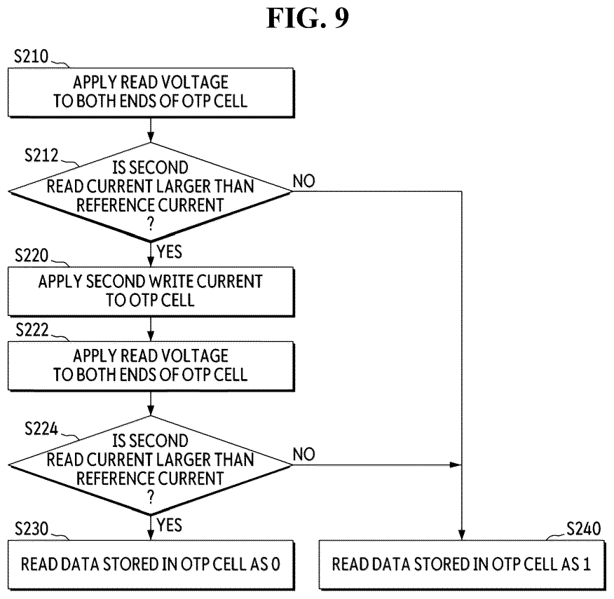

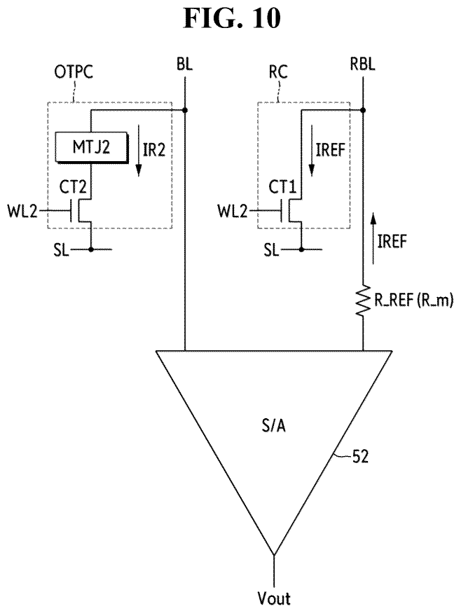

FIG. 9 is a flowchart for explaining a read operation of the OTP cell according to some embodiments. FIG. 10 is a diagram for explaining the read operation of the OTP cell according to some embodiments.

Referring to FIGS. 7, 9, and 10, in some embodiments, the OTP cell OTPC may perform the read operation, using the reference resistor R_REF having a fixed resistance value. The OTP cell OTPC may be performed using the read method of the memory cell MC of FIG. 8. The read operation of the OTP cell OTPC may be performed by the control circuit of FIG. 1.

The read voltage may be applied to both ends of the OTP cell OTPC and both ends of the reference cell RC at operation S210. At this time, the reference cell RC connected to the reference bit line RBL and the same second word line WL2 as the OTP cell OTPC may be used. A turn-on voltage may be applied to the second word line WL2 of the OTP cell OTPC and the reference cell RC, and the read voltage may be applied to both ends of the OTP cell OTPC and both ends of the reference cell RC. For example, the read voltage may be applied to the bit line BL of the OTP cell OTPC and the reference bit line RBL of the reference cell RC, and the ground voltage may be applied to the source line of the OTP cell OTPC and the source line of the reference cell RC. Accordingly, the second read current IR2 may flow through the OTP cell OTPC, and the reference current IREF may flow through the reference cell RC and the reference resistor R_REF as described using FIG. 8.

Next, it may be determined whether the second read current IR2 flowing through the OTP cell OTPC is greater than the reference current IREF flowing through the reference cell RC and the reference resistor R_REF at operation S212. The sense amplifier 52 may sense a difference between the voltage of the node to which the second read current IR2 is applied and the voltage of the node to which the reference current IREF is applied, amplify the difference, and output the amplified difference as the output voltage Vout. The sense amplifier 52 may determine whether the second read current IR2 is greater than the reference current IREF.

If the second read current IR2 is smaller than the reference current IREF at operation S212, the OTP cell OTPC may be determined to be in the anti-parallel state AP. For example, because the OTP cell OTCP is not in an break-down state, the data stored in the OTP cell OTPC may be read as having a value of one (“1”) at operation S240.

If the second read current IR2 is greater than the reference current IREF at operation S212, a second write current IW2 may be applied to the OTP cell OTPC at operation S220. The second write current IW2 may be a current used to write the memory cell MC to the anti-parallel state AP.

Next, the read voltage may be applied to both ends of the OTP cell OTPC and both ends of the reference cell RC at operation S222. As described at operation S210, the second read current IR2 may flow through the OTP cell OTPC, and the reference current IREF may flow through the reference cell RC and the reference resistor R_REF.

Next, it may be determined whether the second read current IR2 flowing through the OTP cell OTPC is greater than the reference current IREF at operation S224. As described at operation S212, the sense amplifier 52 may determine whether the second read current IR2 is greater than the reference current IREF.

If the second read current IR2 is greater than the reference current IREF at operation S224, it may be determined that there is no resistance change in the OTP cell OTPC. For example, because the OTP cell OTCP is in the break-down state, the data stored in the OTP cell OTPC may be read as having a value of zero (“0”) at operation S230. If the second read current IR2 is smaller than the reference current IREF at operation S224, it may be determined that the OTP cell OTPC is in the anti-parallel state AP and there is a resistance change in the OTP cell OTPC. For example, because the OTP cell (OTCP) is not in the break-down state, the data stored in the OTP cell OTPC may be read as having a value of one (“1”) at operation S240.

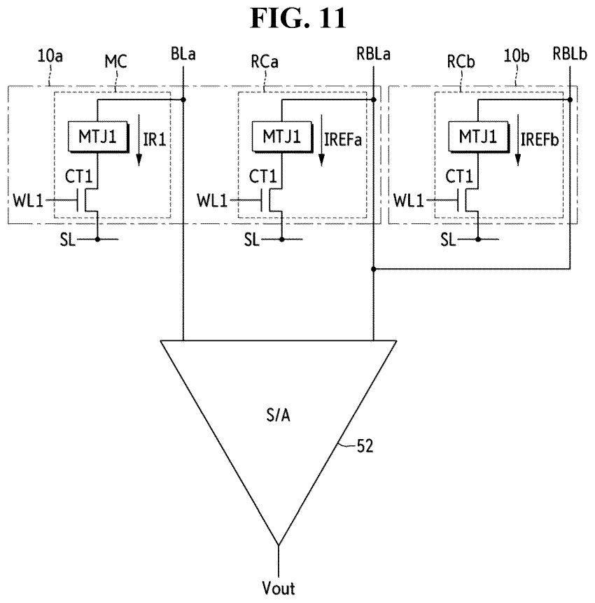

FIG. 11 is a diagram for explaining the read operation of the memory cell according to some embodiments.

Referring to FIG. 11, in some embodiments, the reference cell RCa connected to the first word line WL1 and the reference bit lines RBLa, and the reference cell RCb connected to the first word line WL1 and the reference bit line RBLb, may have substantially the same structure as the memory cell MC. Each of the reference cells RCa and RCb may include a first magnetic tunnel junction element MTJ1 and a first cell transistor CT1. The memory cell MC may perform the read operation using the reference cells RCa and RCb. The read operation of the memory cell MC may be performed by the control circuit of FIG. 1.

In some embodiments, the memory cell MC may perform the read operation, using the reference cells RCa and RCb. The reference resistor value (e.g., the reference resistor value R_m of FIG. 5) may be generated, using the plurality of reference cells RCa and RCb.

For example, the cell array 10 of FIG. 1 may include a first cell array 10a and a second cell array 10b, each of which may include a memory cell array 11 and an OTP cell array 12. The input/output circuit 70 may include a first input/output circuit connected to the first cell array 10a, and a second input/output circuit connected to the second cell array 10b. That is, the first cell array 10a and the second cell array 10b may be connected to different input/output circuits from each other. The first cell array 10a may include a first reference cell RCa connected to a first reference bit line RBLa, and the second cell array 10b may include a second reference cell RCb connected to a second reference bit line RBLb. To perform a read operation on the memory cell MC connected to the first bit line BLa, the first reference cell RCa and the second reference cell RCb connected to different input/output circuits from each other may be used.

For example, the first magnetic tunnel junction element MTJ1 of the first reference cell RCa and the first magnetic tunnel junction element MTJ1 of the second reference cell RCb may have different resistance values from each other. For example, the first magnetic tunnel junction element MTJ1 of the first reference cell RCa may have a first resistance value R_P in a parallel state, and the first magnetic tunnel junction element MTJ1 of the second reference cell RCb may have a second resistance value R_AP in an anti-parallel state.

For the read operation of the memory cell MC, a turn-on voltage may be applied to the first word line WL1 of the memory cell MC, the first reference cell RCa, and the second reference cell RCb, and the read voltage may be applied to both ends of the memory cell MC, both ends of the first reference cell RCa, and both ends of the second reference cell RCb. Accordingly, a first read current IR1 may flow through the memory cell MC, a first reference current IREFa may flow through the first reference cell RCa, and a second reference current IREFb may flow through the reference cell RCb. The sum of the first reference current IREFa and the second reference current IREFb may be the same as the reference current (e.g., the reference current IREF of FIG. 8 or FIG. 10). The sense amplifier 52 may sense a difference between the voltage of a node to which the first read current IR1 is applied and the voltage of a node to which the first reference current IREF1 and the second reference current IREF2 are applied, and may amplify the difference. The difference in the amplified voltage may be output as an output voltage Vout, and may be used to discriminate the data that is read from the memory cell MC. For example, the sense amplifier 52 may compare the sum of the first reference current IREF1 and the second reference current IREF2 with the first read current IR1.

However, these are only examples, and embodiments are not limited thereto. For example, a number of the plurality of reference cells RCa and RCb used for the read operation of the memory cell MC and the resistance values of each of the reference cells RCa and RCb are not limited thereto.

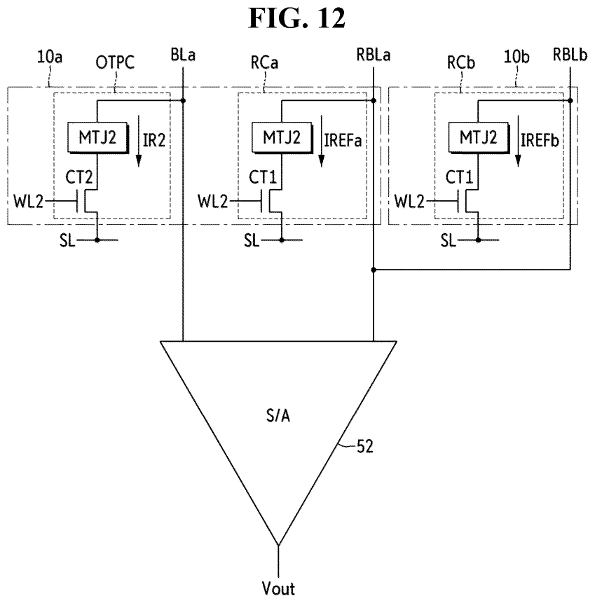

FIG. 12 is a diagram for explaining the read operation of the OTP cell.

Referring to FIG. 12, in some embodiments, the reference cell RCa connected to the second word line WL2 and the reference bit line RBLa, and the reference cell RCb connected to the second word line WL2 and the reference bit line RBLb, may have substantially the same structure as the OTP cell OTPC. Each of the reference cells RCa and RCb may include a second magnetic tunnel junction element MTJ2 and a second cell transistor CT2. The OTP cell OTPC may perform the read operation, using a the reference cells RCa and RCb. The OTP cell OTPC may be read, using the read method of the memory cell MC of FIG. 11. The read operation of the OTP cell OTPC may be performed by the control circuit of FIG. 1.

Referring to FIGS. 9 and 12, at operations S210 and S222, the read voltage may be applied to both ends of the OTP cell OTPC and both ends of the first and second reference cells RCa and RCb. at operations S212 and S224, the sense amplifier 52 may sense the difference between the voltage of the node to which the second read current IR2 is applied and the voltage of the node to which the first reference current IREF1 and the second reference current IREF2 are applied, and amplify the difference. The difference in the amplified voltage may be output as the output voltage Vout, and may be used to discriminate data that is read from the memory cell MC. The sense amplifier 52 may compare the sum of the first reference current IREF1 and the second reference current IREF2 with the second read current IR2.

In the magnetic memory device according to some embodiments, the read operation of the OTP cell OTPC may be performed without a reference resistor having a value between the third resistance value R_BD and the first resistance value R_P of FIG. 5. Also, the read operation of the OTP cell OTPC may be performed, using the read operation method of the memory cell MC and the write operation method of the memory cell MC. Therefore, because the read operation of the OTP cell OTPC may be performed without a separate configuration for performing the read operation of the OTP cell OTPC, the configuration of the magnetic memory device may be simplified, and the operation of the magnetic memory device may be simplified.

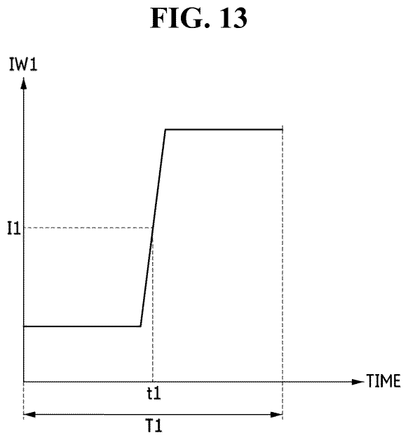

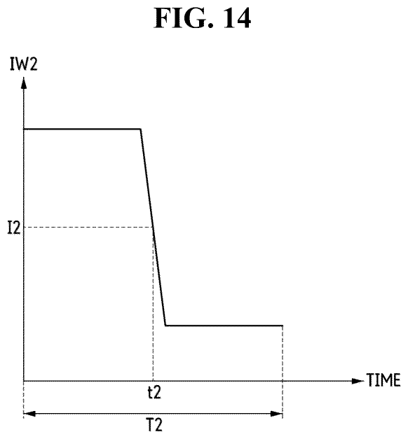

FIGS. 13 and 14 are diagrams for explaining the operation of the magnetic memory device according to some embodiments.

Referring to FIGS. 3, 13, and 14, in order to write the memory cell MC to the parallel state P or the anti-parallel state AP, the write voltage may be applied to both ends of the memory cell MC for specific amounts of time, for example a time T1 and a time T2. Accordingly, the write currents IW1 and IW2 may flow through the memory cell MC.

If the resistance value of the first magnetic tunnel junction element MTJ1 of the memory cell MC changes at time points t1 and t2 before the specific times T1 and T2, the magnitude of the write currents IW1 and IW2 flowing through the memory cell MC may decrease or increase. For example, the write operation of the memory cell MC may be completed at the time points t1 and t2, and it may not be necessary to apply the write voltage to the memory cell MC after the time points t1 and t2. Thus, in some embodiments, the magnitudes of the write currents IW1 and IW2 flowing through the memory cell MC at the specific times T1 and T2 may be monitored, and if the magnitudes of the write currents IW1 and IW2 decrease or increase before the specific times T1 and T2, the application of the write voltage to the memory cell MC is ended and the write operation may be ended. Accordingly, the write power of the memory cell MC may be reduced. If the magnitudes of the write currents IW1 and IW2 do not change at the specific times T1 and T2, the write operation may be ended at the time point when the specific times T1 and T2 have passed. The monitoring of the write currents IW1 and IW2 and the write operation of the memory cell MC may be performed by the control circuit of FIG. 1.

For example, in an operation of writing the memory cell MC to the parallel state P, a first write current IW1 may be applied to the memory cell MC. If the magnitude of the first write current IW1 flowing through the memory cell at a first time point t1 before the first time T1 is equal to or greater than a first current value I1, the write operation of the memory cell MC may be ended at the first time point t1. In the operation of writing the memory cell MC to the parallel state P, a second write current IW2 may be applied to the memory cell MC. If the magnitude of the second write current IW2 flowing through the memory cell MC at a second time point t2 before the second time T2 is equal to or less than the second current value I2, the write operation of the memory cell MC may be ended at the second time point t2.

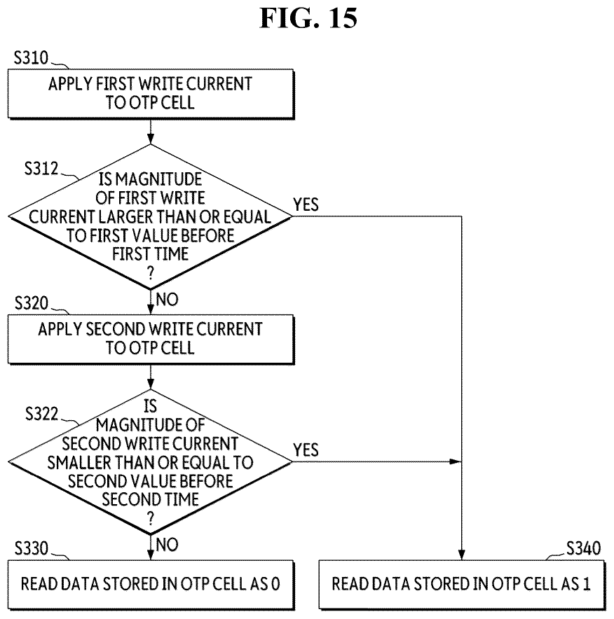

FIG. 15 is a flowchart for explaining the read operation of the OTP cell according to some embodiments.

Referring to FIGS. 7 and 13 to 15, in some embodiments, the presence or absence of a resistance change in the OTP cell OTPC (e.g., operation S120 of FIG. 6) may be determined, using the write operation of the memory cell MC, which may sense a change in the magnitude of the write currents IW1 and IW2 for the specific times T1 and T1 discussed above to end the write operation. The presence or absence of a resistance change in the OTP cell OTPC may be determined, using whether the magnitudes of the write currents IW1 and IW2 flowing through the OTP cell OTPC change when the write voltage is applied to both ends of the OTP cell.

The first write current IW1 may be applied to the OTP cell OTPC at operation S310. The first write current IW1 may be a current used to write the memory cell MC to the parallel state P.

Next, it may be determined whether the magnitude of the first write current IW1 is equal to or greater than a first value I1 before the first time T1 at operation S312.

If the magnitude of the first write current IW1 is equal to or greater than the first value I1 before the first time T1 at operation S312, it may be determined that there is a resistance change in the OTP cell OTPC, and because the OTP cell OTCP is not in an break-down state, the data stored in the OTP cell OTPC may be read as having a value of one (“1”) at operation S340.

If the magnitude of the first write current IW1 is not equal to or greater than the first value I1 during the first time T1 at operation S312, the second write current IW2 may be applied to the OTPC cell OTPC at operation S320. The second write current IW2 may be a current that is used to write the memory cell MC to the anti-parallel state AP.

Next, it may be determined whether the magnitude of the second write current IW2 is equal to or less than the second value I2 before the second time T2 at operation S322.

If the magnitude of the second write current IW2 is equal to or less than the second value I2 before the second time T2 at operation S322, it may be determined that there is a resistance change in the OTP cell OTPC, and because the OTP cell OTCP is not in the break-down state, the data stored in the OTP cell OTPC may be read as having a value of one (“1”) at operation S340.

If the magnitude of the second write current IW2 is not equal to or less than the second value I2 during the second time T2 at operation S322, because the OTP cell OTCP is in the break-down state, the data stored in the OTP cell OTPC may be read as having a value of zero (“0”) at operation S330.

When the second magnetic tunnel junction MTJ2 of the OTP cell OTPC is in a state of being dielectrically broken down, the resistance of the OTP cell OTPC may not change, even if the write currents IW1 and IW2 are applied to the OTP cell OTPC. Therefore, if the magnitude of the first write current IW1 does not change to the first current value I1 or more before the first time T1 and the magnitude of the second write current IW2 does not change to the second current value I2 or less before the second time T2, it may be determined that there is no change in the resistance of the OTP cell OTPC, and the data stored in the OTP cell OTPC may be read as having a value of zero (“0”).

However, when the second magnetic tunnel junction MTJ2 of the OTP cell OTPC is not in the state of being dielectrically broken down, the resistance of the OTP cell OTPC may change when the write currents IW1 and IW2 are applied to the OTP cell OTPC. When the state corresponds to at least one of a case where the magnitude of the first write current IW1 is changed to the first current value I1 or more before the first time T1, and a case where the magnitude of the second write current IW2 is changed to the second current value I2 or less before the second specific time T2, it may be determined that there is a resistance change in the OTP cell OTPC, and the data stored in the OTP cell OTPC may be read as having a value of one (“1”).

In the magnetic memory device according to some embodiments, the read operation of the OTP cell OTPC may be performed without a reference resistor having a value between the third resistance value R_BD and the first resistance value R_P of FIG. 5. In addition, the read operation of the OTP cell OTPC may be performed, using the write operation method of the memory cell MC. Therefore, because the read operation of the OTP cell OTPC may be performed without a separate configuration for performing the read operation of the OTP cell OTPC, the configuration of the magnetic memory device may be simplified and the operation of the magnetic memory device may be simplified.

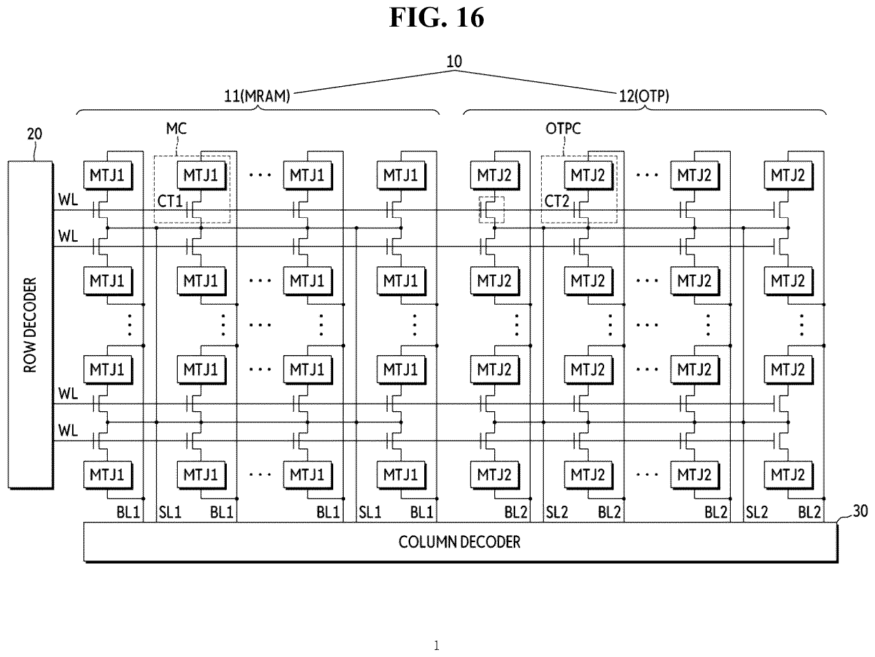

FIG. 16 is an exemplary circuit diagram for explaining a magnetic memory device according to some embodiments. For convenience of explanation, description that is redundant or duplicative of the description of FIGS. 1 to 15 provided above may be briefly explained or omitted.

Referring to FIG. 16, in some embodiments, the OTP cells OTPC may be connected to a specific bit line. The memory cells MC and the OTP cells OTPC may be connected to different bit lines from each other. For example, the memory cells MC may be connected to the first bit line BL1, and the OTP cells OTPC may be connected to the second bit line BL2. The memory cells MC and the OTP cells OTPC may be connected to one word line WL. For example, the OTP cells OTPC may be connected to the second bit line BL2 disposed at an edge portion of a cell array 10. In addition, the memory cells MC may be connected to the first source line SL1, and the OTP cells OTPC may be connected to a second source line SL2 different from the first source line SL1.

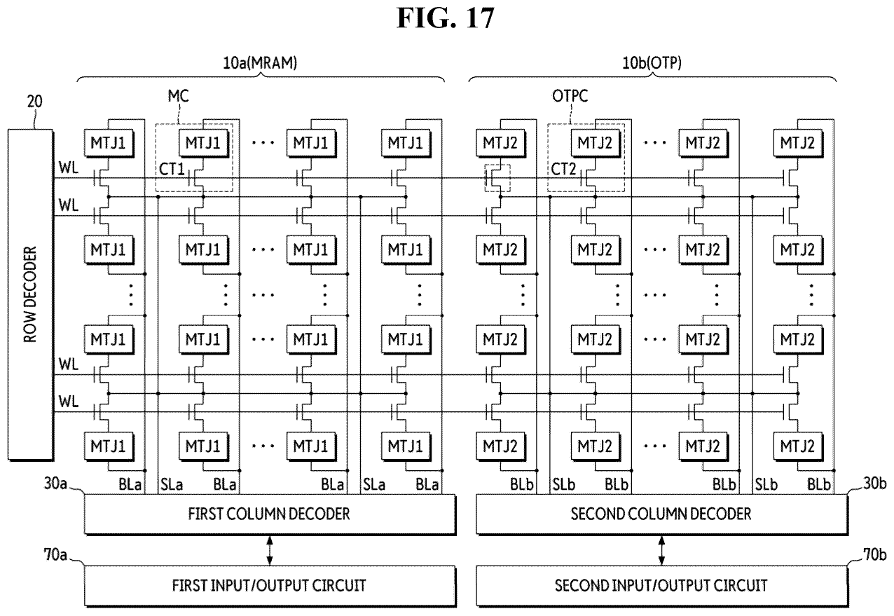

FIG. 17 is an exemplary circuit diagram for explaining a magnetic memory device according to some embodiments. For convenience of explanation, repeated parts of those explained above using FIGS. 1 to 15 will be briefly explained or omitted.

Referring to FIGS. 1 and 17, in some embodiments, the OTP cells OTPC may be disposed on a cell array (e.g., a second cell array 10b) connected to a specific input/output circuit (e.g., a second input/output circuit 70b).

The cell array 10 may include a plurality of cell arrays. Each cell array may be connected to respective input/output circuits and column decoders. For example, the cell array 10 may include a first cell array 10a and a second cell array 10b. The input/output circuit 70 may include a first input/output circuit 70a connected to the first cell array 10a, and a second input/output circuit 70b connected to the second cell array 10b. The column decoder 30 may include a first column decoder 30a connected to the first cell array 10a, and a second column decoder 30b connected to the second cell array 10b.

The first cell array 10a may include the OTP cells OTPC, and the second cell array 10b may include the memory cells MC. Only the OTP cells OTPC may be connected to the first bit line BLa of the first cell array 10a, and only the memory cells MC may be connected to the second bit line BLb of the second cell array 10b. The memory cells MC and the OTP cells OTPC may be connected to one word line WL. The memory cells MC and the OTP cells OTPC may be connected to different input/output circuits from each other. For example, the OTP cells OTPC may be disposed in the second cell array 10b disposed at the edge portion of the cell array 10.

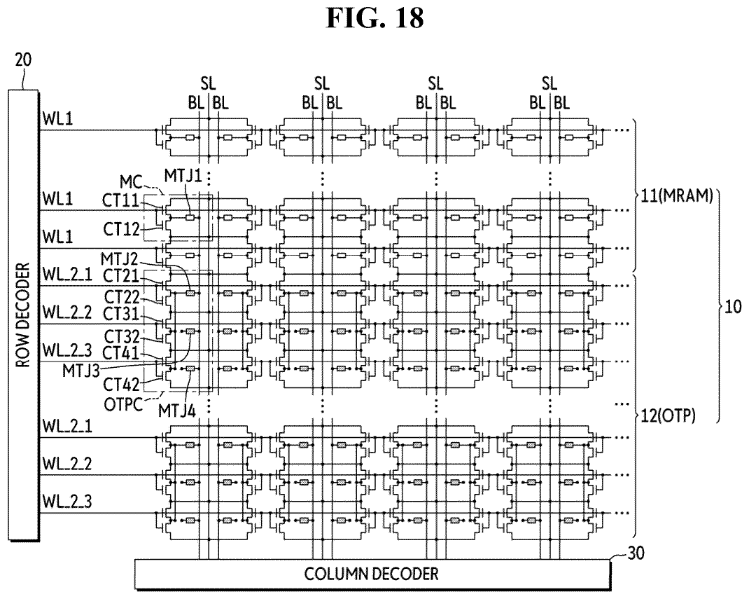

FIG. 18 is an exemplary circuit diagram for explaining a magnetic memory device according to some embodiments. For convenience of explanation, repeated parts of those explained above using FIGS. 1 to 15 will be briefly explained or omitted.

Referring to FIGS. 1 and 18, in some embodiments, the OTP cells OTPC may include a plurality of magnetic tunnel junction elements MTJ2, MTJ3, and MTJ4 and a plurality of cell transistors CT21, CT22, CT31, CT32, CT41, and CT42. The OTP cell OTPC may be connected to the second word lines WL_2_1, WL_2_2, and WL_2_3.

For example, the OTP cell OTPC may include a second magnetic tunnel junction element MTJ2, second cell transistors CT21 and CT22, a third magnetic tunnel junction element MTJ3, third cell transistors CT31 and CT32, a fourth magnetic tunnel junction element MTJ4, and fourth cell transistors CT41 and CT42.

The second cell transistors CT21 and CT22, the third cell transistors CT31 and CT32, and the fourth cell transistors CT41 and CT42 may be connected in parallel. The number of cell transistors included in the OTP cell OTPC is not limited thereto.

One end of the second magnetic tunnel junction element MTJ2 may be connected to the bit line BL, and another end of the second magnetic tunnel junction element MTJ2 may be connected to one end of a second-first cell transistor CT21 and one end of a second-second cell transistor CT22. Another end of the second-first cell transistor CT21 and another end of the second-second cell transistor CT22 may be connected to the source line SL. The gate electrode of the second-first cell transistor CT21 and the gate electrode of the second-second cell transistor CT22 may be connected to a second-first word line WL_2_1. The second-first cell transistor CT21 and the second-second cell transistor CT22 may be turned on or off by a signal or voltage provided through the second-first word line WL_2_1.

One end of the third magnetic tunnel junction element MTJ3 may be connected to the bit line BL. Another end of the third magnetic tunnel junction element MTJ3 may be not connected to one end of a third-first cell transistor CT31 and one end of a third-second cell transistor CT32, and the third magnetic tunnel junction element MTJ3 may be electrically isolated from the third cell transistors CT31 and CT32. One end of the third-first cell transistor CT31 and one end of the third-second cell transistor CT32 may be connected to the other end of the second magnetic tunnel junction element MTJ2. Another end of the third-first cell transistor CT31 and another end of the third-second cell transistor CT32 may be connected to the source line SL. The gate electrode of the third-first cell transistor CT31 and the gate electrode of the third-second cell transistor CT32 may be connected to a second-second word line WL_2_2. The third-first cell transistor CT31 and the third-second cell transistor CT32 may be turned on or off by a signal or voltage provided through the second-second word line WL_2_2.

One end of the fourth magnetic tunnel junction element MTJ4 may be connected to the bit line BL, another end of the fourth magnetic tunnel junction element MTJ4 may be not connected to one end of a fourth-first cell transistor CT41 and one end of a fourth-second cell transistor CT42, and the fourth magnetic tunnel junction element MTJ4 may be electrically isolated from the fourth cell transistors CT41 and CT42. One end of the fourth-first cell transistor CT41 and one end of the fourth-second cell transistor CT42 may be connected to the other end of the second magnetic tunnel junction element MTJ2. Another end of the fourth-first cell transistor CT41 and another end of the fourth-second cell transistor CT42 are connected to the source line SL. The gate electrode of the fourth-first cell transistor CT41 and the gate electrode of the fourth-second cell transistor CT42 may be connected to a second-third word line WL_2_3. The fourth-first cell transistor CT41 and the fourth-second cell transistor CT42 may be turned on or off by a signal or voltage provided through the second-third word line WL_2_3.

The third and fourth magnetic tunnel junction elements MTJ3 and MTJ4 may be dummy magnetic tunnel junction elements. The third and fourth magnetic tunnel junction elements MTJ3 and MTJ4 may be unused magnetic tunnel junction elements.

Each of the pair of the second magnetic tunnel junction element MTJ2 and the second cell transistors CT21 and CT22 of the OTP cell OTPC, the pair of the third magnetic tunnel junction element MTJ3 and the third cell transistors CT31 and CT32, and the pair of the fourth magnetic tunnel junction element MTJ4 and the fourth cell transistors CT41 and CT42 may be disposed in the cell array 10 to have the same repeating periodicity as the pair of the first magnetic tunnel junction element MTJ1 and the first cell transistors CT11 and CT12 of the memory unit cell MC.

In some embodiments, a read path and a write path of the OTP cell OTPC may be separated. Some of the second to fourth cell transistors CT21, CT22, CT31, CT32, CT41, and C42 of the OTP cell OTPC may be used at the time of the read operation of the OTP cell OTPC, and the rest may be used at the time of the write operation of the OTP cell OTPC.

For example, the second cell transistors CT21 and CT22 connected to the second-first word line WL_2_1 may be used at the time of the read operation of the OTP cell OTPC, and the third cell transistors CT31 and CT32 connected to the second-second word line WL_2_2 and the fourth cell transistors CT41 and CT42 connected to the second-third word line WL_2_3 may be used at the time of the write operation of the OTP cell OTPC.

For example, the second-second word line WL_2_2 and the second-third word line WL_2_3 may be connected. The second-second word line WL_2_2 and the second-third word line WL_2_3 may be the same word line. The gates of the third cell transistors CT31 and CT32 and the fourth cell transistors CT41 and CT42 may be operated by the same word line voltage, and may be operated by a different word line voltage from the gates of the second cell transistors CT21 and CT22.

However, embodiments are not limited thereto, and in some emboidments, the second-first to second-third word lines WL_2_1, WL_2_2 and WL_2_3 may be different word lines from each other. For example, the gates of the second cell transistors CT21 and CT22, the gates of the third cell transistors CT31 and CT32, and the gates of the fourth cell transistors CT41 and CT42 may be operated by different word line voltages from each other.

In some other embodiments, the read path and the write path of the OTP cell OTPC may not be separated. The second to fourth cell transistors CT21, CT22, CT31, CT32, CT41, and CT42 of the OTP cell OTPC may be used at the time of both read and write operations of the OTP cell OTPC.

Although the embodiments of the present disclosure are described above with reference to the accompanying drawings, the present disclosure is not limited to the above embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A magnetic memory device comprising:
a cell array comprising:
a memory cell comprising a first magnetic tunnel junction element, and
a one-time-programmable (OTP) cell comprising a second magnetic tunnel junction element; and
a control circuit configured to perform a read operation on the OTP cell by applying a write current to the OTP cell, and determining whether a resistance of the OTP cell changes after the write current is applied to the OTP cell.

2. The magnetic memory device of claim 1,
wherein the cell array further comprises a reference cell comprising a third magnetic tunnel junction element, and
wherein the control circuit is further configured to determine whether the resistance of the OTP cell changes using the reference cell.

3. The magnetic memory device of claim 1,
wherein the control circuit is further configured to determine whether the resistance of the OTP cell changes using a reference resistor having a fixed resistance value.

4. The magnetic memory device of claim 1,
wherein the cell array further comprises:
a first reference cell comprising a third magnetic tunnel junction element, and
a second reference cell including a fourth magnetic tunnel junction element, and
wherein the control circuit is further configured to perform the read operation on the memory cell using the first reference cell and the second reference cell, and control whether the resistance of the OTP cell changes using the first reference cell and the second reference cell

5. The magnetic memory device of claim 4,
wherein the first reference cell is connected to a first input/output circuit, and
wherein the second reference cell is connected to a second input/output circuit different from the first input/output circuit.

6. The magnetic memory device of claim 1,
wherein the control circuit is further configured to determine whether the resistance of the OTP cell changes based on a change in a magnitude of the write current while the write current is applied to the OTP cell.

7. The magnetic memory device of claim 1,
wherein the memory cell is connected to a first word line, and
wherein the OTP cell is connected to a second word line different from the first word line.

8. The magnetic memory device of claim 1,
wherein the memory cell is connected to a first bit line, and
wherein the OTP cell are connected to a second bit line different from the first bit line.

9. The magnetic memory device of claim 1,
wherein the memory cell is connected to a first input/output circuit, and
wherein the OTP cell is connected to a second input/output circuit different from the first input/output circuit.

10. The magnetic memory device of claim 1,
wherein the memory cell and the OTP cell are connected to a same input/output circuit.

11. The magnetic memory device of claim 1,
wherein the OTP cell is connected to a bit line and a source line, and
wherein the write current comprises a first write current which flows from the bit line to the source line, and a second write current which flows from the source line to the bit line.

12. The magnetic memory device of claim 1,
wherein a magnitude of the write current is smaller than a magnitude of a break-down current for writing the OTP cell in a break-down state.

13. A magnetic memory device comprising:
a cell array comprising:
a memory cell comprising a first magnetic tunnel junction element and a first cell transistor, and
an OTP cell comprising a second magnetic tunnel junction element and a second cell transistor; and
a control circuit configured to:
apply a write current to the memory cell to perform a write operation on the memory cell, and
apply the write current to the OTP cell to perform a read operation on the OTP cell.

14. The magnetic memory device of claim 13,
wherein the memory cell further comprises a reference cell comprising a third magnetic tunnel junction element and a third cell transistor, and
wherein the control circuit is further configured to perform the read operation on the OTP cell by comparing a read current flowing through the OTP cell with a reference current flowing through the reference cell.

15. The magnetic memory device of claim 13,
wherein the memory cell further comprises a reference cell including a third cell transistor,
wherein the reference cell is connected to a resistor having a constant resistance value, and
wherein the control circuit is further configured to perform the read operation on the OTP cell by comparing a read current flowing through the OTP cell with a reference current flowing through the resistor and the reference cell.

16. The magnetic memory device of claim 13,
wherein the control circuit is further configured to perform the read operation on the OTP cell by determining whether a magnitude of the write current flowing through the OTP cell changes.

17. The magnetic memory device of claim 13,
wherein the control circuit is further configured to end the write operation on the memory cell based on a change in a magnitude of the write current flowing through the memory cell.

18. The magnetic memory device of claim 13,
wherein the first cell transistor and the second cell transistor are gated to a same word line.

19. The magnetic memory device of claim 13,
wherein the first cell transistor is gated to a first word line, and
wherein the second cell transistor is gated to a second word line different from the first word line.

20. A magnetic memory device, comprising:
a cell array comprising a reference cell including a first magnetic tunnel junction element, a memory cell, and an OTP cell including a second magnetic tunnel junction element; and
a control circuit configured to:
perform a read operation on the memory cell using the reference cell,
apply a write current to the OTP cell, and
perform a read operation on the OTP cell based on a change in a magnitude of a current flowing through the reference cell or the write current.
